(19) United States
(12) Patent Application Publication
(10) Pub. No.: US 2007/0059892 A1
(43) Pub. Date: Mar. 15, 2007

(54) Method for fabricating a semiconductor structure

(76) Inventors: Matthias Kroenke, Dresden (DE); Dirk Offenberg, Dresden (DE)

Correspondence Address: SLATER & MATSIL LLP, 17950 PRESTON ROAD, SUITE 1000, DALLAS, TX, 75252, US

(21) Appl. No.: 11/513,835

(22) Filed: Aug. 31, 2006

(30) Foreign Application Priority Data
Aug. 31, 2005 (DE) 102005042071.0-33

(51) Int. Cl. H01L 21/336

(52) U.S. Cl. 438/300; 438/303

(57) ABSTRACT

A semiconductor structure is fabricated to have a transistor cell region and a connection region. The transistors both of a transistor cell region and of a connection region are coated with a first oxide layer, the layer thickness of the first oxide layer being dimensioned in such a way that a gap region in each case remains present between the adjacent transistors in the transistor cell region. A sacrificial structure is subsequently applied between at least two adjacent transistors of the transistor cell region in the gap region. At least one gap region in each case remains free between two adjacent sacrificial structures. A second oxide layer is applied to the sacrificial structures and the first oxide layer. The first and second oxide layers are subjected to an etching step in which at least one spacer having a predetermined spacer width is formed on the side edges of at least one transistor of the connection region, the spacer being formed by the first and second oxide layers and the spacer width being determined by the layer thickness of the first and second oxide layers and also by the etching step.

This application claims priority to German Patent Application 10 2005 042 071.0-33, which was filed Aug. 31, 2005 and is incorporated herein by reference.

### TECHNICAL FIELD

The invention relates to a method for fabricating a semiconductor structure having a transistor cell region (or cell array), in which transistors are arranged closely adjacent alongside one another, and having a connection region, in which transistors are at a greater distance from one another than in the transistor cell region.

### BACKGROUND

Semiconductor structures of this type are used for example in the fabrication of memory cells such as DRAM memory cells. The transistor cell region, in which the transistors are arranged closely adjacent alongside one another forms the actual memory region in said memory cells. The memory region also contains capacitors in addition to the transistors, which capacitors are connected to the transistors and in which capacitors the items of information to be stored are stored in the form of electrical charges. The connection region of such a memory cell is to be differentiated from the memory region; in the connection region, the transistors are at a greater distance from one another than in the transistor cell region. Different transistors, for example, transistors that have a higher electrical loading capacity or are faster, than in the transistor cell region are usually used in the connection region.

### SUMMARY OF THE INVENTION

In one aspect, the invention specifies a method that enables a simple and readily reproducible fabrication of spacers on or at the transistors of the aforementioned connection region.

The term “spacers” that is customary in the jargon, is to be understood to mean layers which run perpendicular, at least substantially perpendicular, to the surface of the substrate and define a lateral spacing. By way of example, the spacers on the side edges of an elevated structure may serve as an implantation mask and ensure that, during an implantation, the implantation substances directed onto the substrate cannot penetrate onto regions of the substrate whose width is defined by the spacers. Spacers may also serve for electrical insulation.

Accordingly, embodiments of the invention provide for the transistors both of the transistor cell region and of the connection region to be coated with a first, preferably conformal oxide layer. The layer thickness of said first oxide layer is dimensioned in such a way that a gap region in each case remains present between adjacent transistors in the transistor cell region. A sacrificial structure is subsequently applied in the gap region between at least two adjacent transistors of the transistor cell region, at least one gap region in each case remaining free, that is to say without a sacrificial structure, between two adjacent sacrificial structures. A second, preferably conformal, oxide layer is then applied to the sacrificial structures and to the first oxide layer. The first and second oxide layers are then subjected to an etching step in which a spacer having a predetermined spacer width is formed on the side edges of at least one transistor of the connection region. The spacer is formed by the first and second oxide layers and the spacer width is determined by the layer thickness of the first and second oxide layers and also by the etching step.

One advantage of a preferred embodiment of the invention can be seen in the fact that an oxide layer is deposited on the sacrificial structures. An oxide layer can be removed from the sacrificial structures during the further processing, for example, during a subsequent CMP (chemical mechanical polishing) step, significantly better than other material layers such as, by way of example, a silicon nitride layer.

Another advantage of some embodiments of the invention can be seen in the fact that the spacer width can be set very accurately and reproducibly because the spacers are exclusively formed by layers of one and the same material in the case of the invention. Consequently, it is possible to effect significantly better control during spacer fabrication, in particular during spacer etching, and during the setting of the spacer width than is the case with spacers that comprise two different materials such as an oxide as first layer and a nitride as second layer.

Field effect transistors are preferably fabricated as transistors. In this case, the spacers are preferably formed in each case on the side edges of the gate contact of the transistors of the connection region.

It can be regarded as advantageous, moreover, if the second oxide layer is deposited with a layer thickness such that the gap regions without a sacrificial structure in the transistor cell region are completely filled with oxide material. The advantage of this measure is that prior to carrying out the etching step for forming the spacers, it is not necessary to cover the gap regions beforehand—for example, with an etching protective layer (e.g., resist layer)—this is because the second oxide layer alone is already sufficient for covering the gap regions.

An anisotropic etching method is preferably used for fabricating the spacers. If the width of the spacers is subsequently intended to be additionally “readjusted” then it is possible, by way of example, to carry out a second etching step with a lateral etching rate or with an isotropic etching behavior and thus subsequently reduce the width of the spacers.

As an alternative, for fabricating the spacers it is also possible to use an etching method which, although it is essentially anisotropic, also affects slight etching in a lateral direction and, consequently, has at least also an “isotropic” behavior. With the use of such an etching method, the resulting spacer width can already be reduced during etching, so that a desired spacer width can still be set very accurately even if one of the two or else both oxide layers had originally been applied thicker than necessary.

Material fabricated with TEOS (tetraethyl orthosilicate) has particularly good properties for spacers so that it is regarded as advantageous if a TEOS layer is deposited as a first and/or second oxide layer. TEOS material is preferably used for both layers.

A multilayer contact is preferably fabricated as gate contact, in order to achieve optimum contact properties. By way of example, the multilayer contact is formed by a polysilicon layer and an overlying metal or metal silicide layer.

The sacrificial structures are preferably removed after spacer fabrication, for example after carrying out a CMP step. Afterward, a transistor contact for at least one of the two spatially assigned transistors is preferably fabricated in each case in the cavities that arise as a result in the place of the sacrificial structures. By way of example, the transistor contacts are formed on a source or drain zone of the respective transistor.

The spacers may serve, for example as a mask for an implantation step in which highly doped contact regions are formed within the source and drain regions of the transistors of the connection region. The highly doped contact regions are thus at a distance from one another determined by the width of the spacers.

In order to form memory cells, capacitors are also preferably fabricated in the region of the transistor cell region. The capacitors, together with the transistors of the transistor cell region, form memory cells, in particular DRAM memory cells. By way of example, trench or deep trench capacitors may be fabricated as capacitors, but other types of capacitors can also be used.

Moreover, the method described can also be used in the production of analog or digital logic components or in the production of processors, to be precise irrespective of whether field effect transistors or bipolar transistors are used.

### BRIEF DESCRIPTION OF THE DRAWINGS

The invention is explained in more detail below by way of example, on the basis of exemplary embodiments. In the figures:

FIGS. 1 to 10 show a first exemplary embodiment of the method according to the invention, in which the gap region between transistors of the transistor cell region is covered by an additional protective layer during the fabrication of the spacers in the connection region; and

FIG. 11 shows a second exemplary embodiment of the method according to the invention, in which the gap region between the transistors of the transistor cell region is covered by the second oxide layer and in which, accordingly, an additional protective layer is not required during the fabrication of the spacers in the connection region.

The following list of reference symbols can be used in conjunction with the figures:

| | |
|---|---|
| 10 | Semiconductor substrate |
| 20 | Transistor cell region |
| 30 | Connection region |
| 40 | Transistor |
| 50 | Transistor |
| 60 | Thermal oxide layer |
| 70 | Surface of the semiconductor substrate |
| 80 | Gate contact |
| 90 | Polysilicon layer |
| 100 | Tungsten or tungsten nitride layer |
| 110 | Silicon nitride covering |
| 200 | Transistor |
| 210 | First conformal oxide layer |
| 220 | Polysilicon layer |
| 230 | Silicon nitride hard mask |
| 240 | Silicon nitride layer |
| 250 | Intermediate layer |
| 260 | Photoresist layer |
| 270 | Mask section |
| 300 | Sacrificial structure |
| 310 | Photoresist layer |
| 320 | Arrow |
| 330 | Second conformal oxide layer |
| 340 | Transistor |
| 350 | Gap region |
| 360 | Transistor |
| 370 | Further sacrificial structure |
| 400 | Protective layer |
| 410 | Spacer |
| 420 | Spacer |
| 425 | Side edges |
| 430 | Bottom region |
| 440 | Oxide plug |

### DETAILED DESCRIPTION OF ILLUSTRATIVE EMBODIMENTS

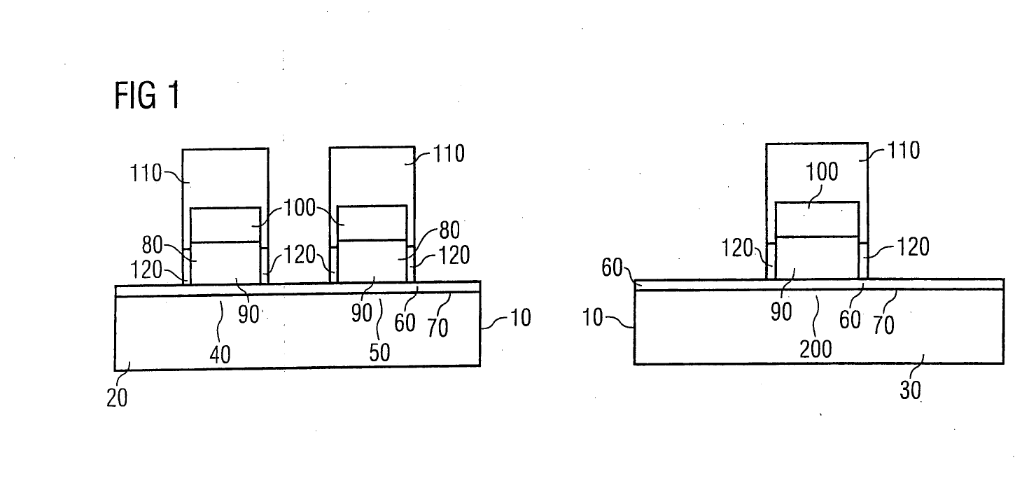

FIG. 1 shows a semiconductor substrate 10 that is formed by a silicon wafer, for example. In FIG. 1 and also in the further figures, the respective partial illustration on the left shows a transistor cell region 20 of the semiconductor substrate 10 and the respective partial illustration on the right shows a connection region 30 of the semiconductor substrate 10. For the sake of clarity, the two regions 20 and 30 are shown separate from one another. The two regions 20 and 30 are nevertheless arranged on one and the same semiconductor substrate 10, to be precise at different locations of the semiconductor substrate 10.

FIG. 1 reveals two transistors 40 and 50 in the transistor cell region 20 of the semiconductor substrate 10; these transistors may be n-channel field effect transistors, by way of example. The gate oxide of said n-channel field effect transistors 40 and 50 is formed by, for example, a thermal oxide layer 60 grown on the surface 70 of the semiconductor substrate 10. The two transistors 40 and 50 are shown as representative of a multiplicity of comparable transistors in the transistor cell region 20.

Gate contacts 80 of the two n-channel field effect transistors 40 and 50 are in each case constructed in two layers and are in each case formed by a polysilicon layer 90 and an overlying tungsten or tungsten nitride layer 100. A silicon nitride covering 110 covers the two gate contacts 80 at the top. The lower part of the gate contacts 80 is covered by a further, for example, thermal oxide layer 120.

FIG. 1 additionally reveals, on the right-hand side, a transistor 200 arranged in the connection region 30. The transistor 200 is, for example, an n-channel field effect transistor or a p-channel field effect transistor. The gate connection region of the transistor 200 essentially corresponds to the gate connection region explained in connection with the two n-channel field effect transistors 40 and 50, so that reference should be made to the above explanations in this regard. Merely the width of the transistor 200 is, for example, greater than the width of the two n-channel field effect transistors 40 and 50. The transistor 200 is shown as representative of a multiplicity of comparable transistors in the connection region 30.

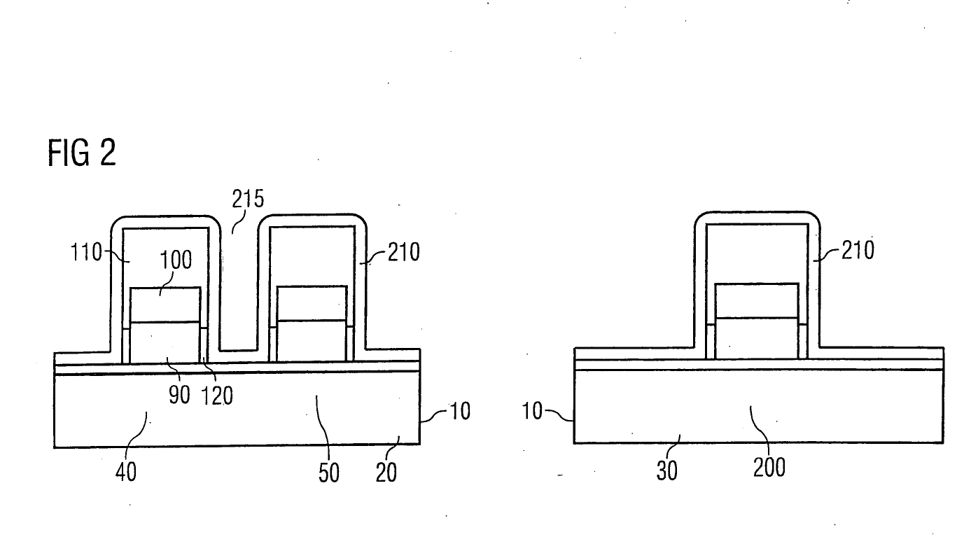

FIG. 2 shows the resulting semiconductor structure after a first conformal oxide layer 210 has been deposited onto the semiconductor substrate 10 over the whole area. The oxide layer 210 is preferably a layer made from TEOS material. The layer thickness of the conformal oxide layer 210 is chosen in such a way that a gap region 215 in each case remains present between the adjacent transistors 40 and 50 in the transistor cell region 20.

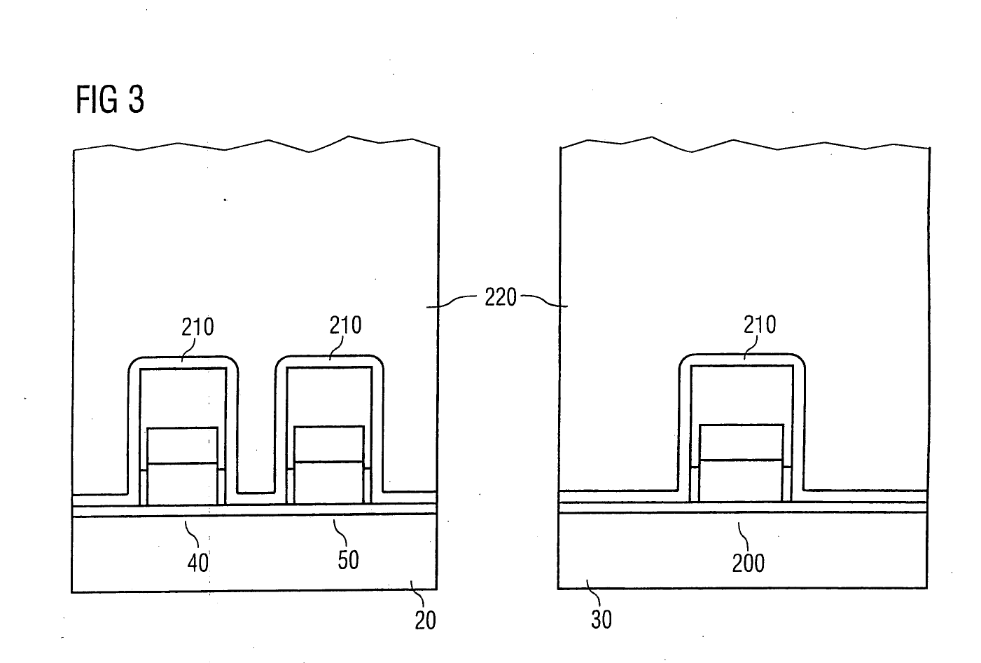

After the deposition of the first oxide layer 210, a polysilicon layer 220 is deposited on the semiconductor substrate 10 over the whole area. The resulting structure is shown in FIG. 3.

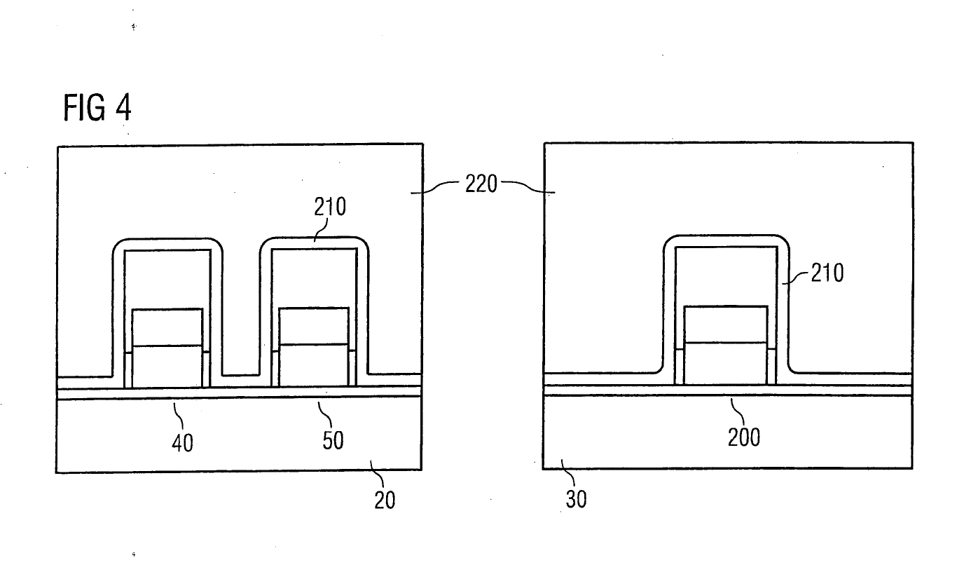

Since the thickness of the polysilicon layer 220 may differ slightly in the transistor cell region 20 and in the connection region 30 on account of the structure differences, a CMP step can subsequently be carried out to achieve a uniform thickness of the polysilicon layer 220 over the semiconductor substrate 10. FIG. 4 shows the resulting structure.

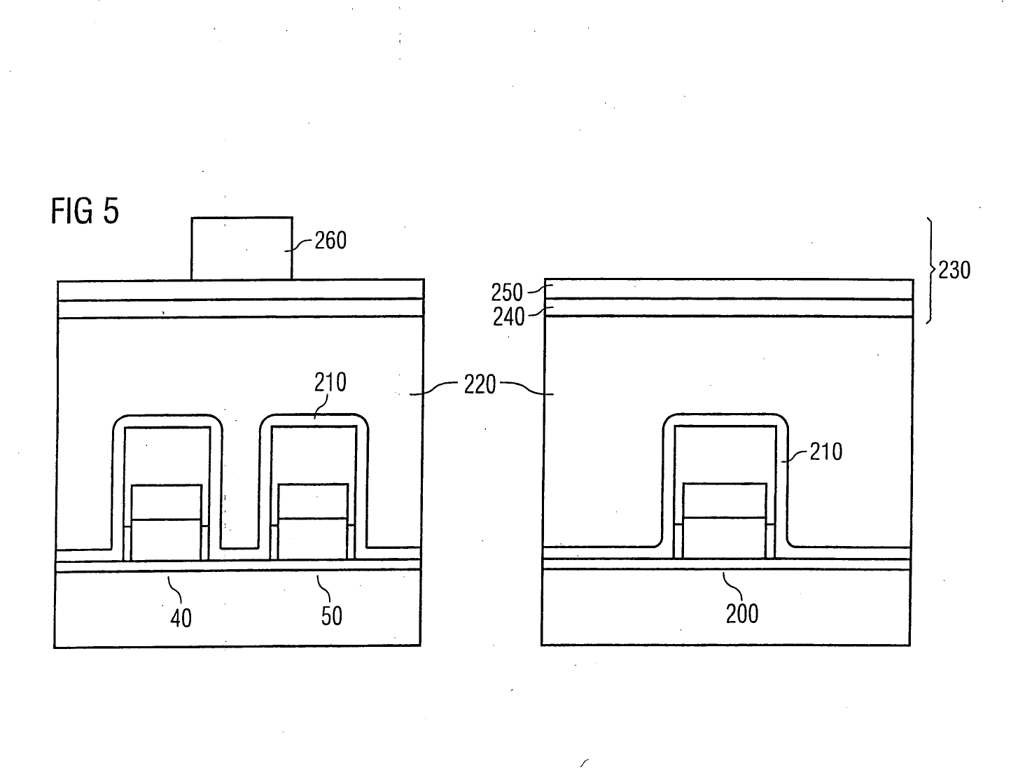

A silicon nitride hard mask 230, comprising a silicon nitride layer 240 and, if appropriate, an intermediate layer 250, and a photoresist layer 260 is subsequently deposited onto the polysilicon layer 220. The photoresist layer 260 has already been patterned in the illustration in accordance with FIG. 5.

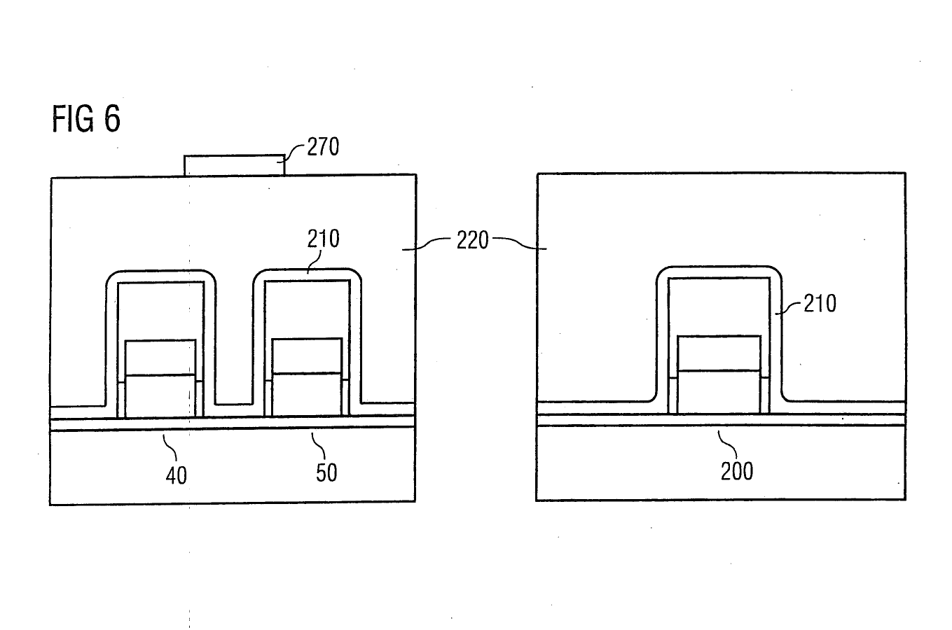

FIG. 6 shows the resulting structure after the patterning of the silicon nitride hard mask 230 has been concluded and the photoresist layer 260 and the intermediate layer 250, if any, have been removed. A mask section 270 can be seen that covers the underlying polysilicon layer 220.

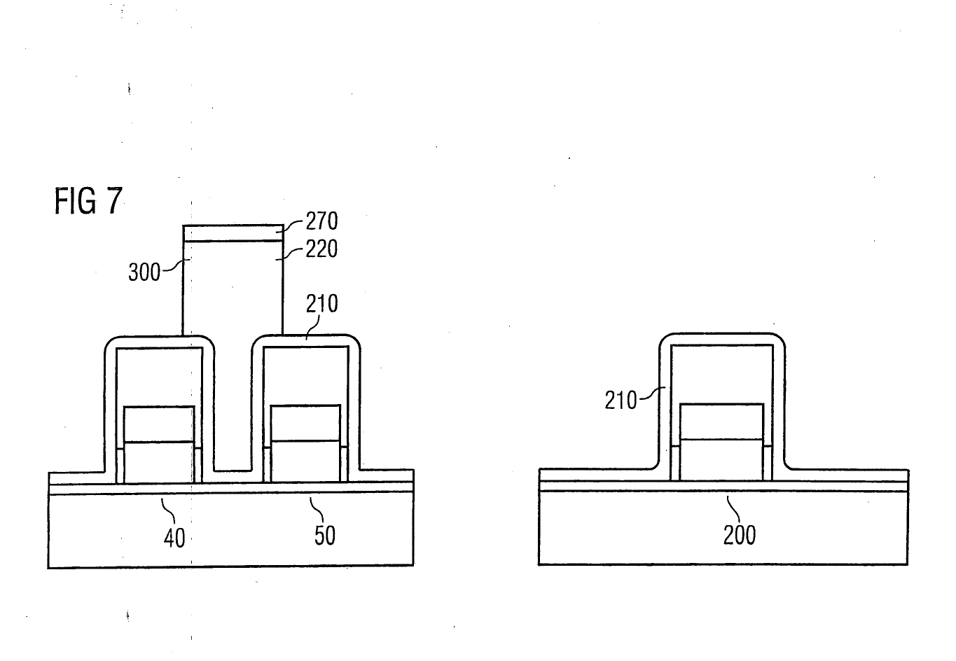

The polysilicon layer 220 is subsequently subjected to an etching step during which the polysilicon is completely removed outside the mask section 270. A sacrificial structure 300 remains under the mask section 270, and may be used for example in a later process stage for forming a transistor contact for at least one of the two transistors 40 and/or 50. The sacrificial structure 300 thus forms as if it were a type of place marker for the later transistor contact. FIG. 7 shows the resulting structure in cross section; viewed from above, the sacrificial structure 300 has a round or oval cross section, by way of example.

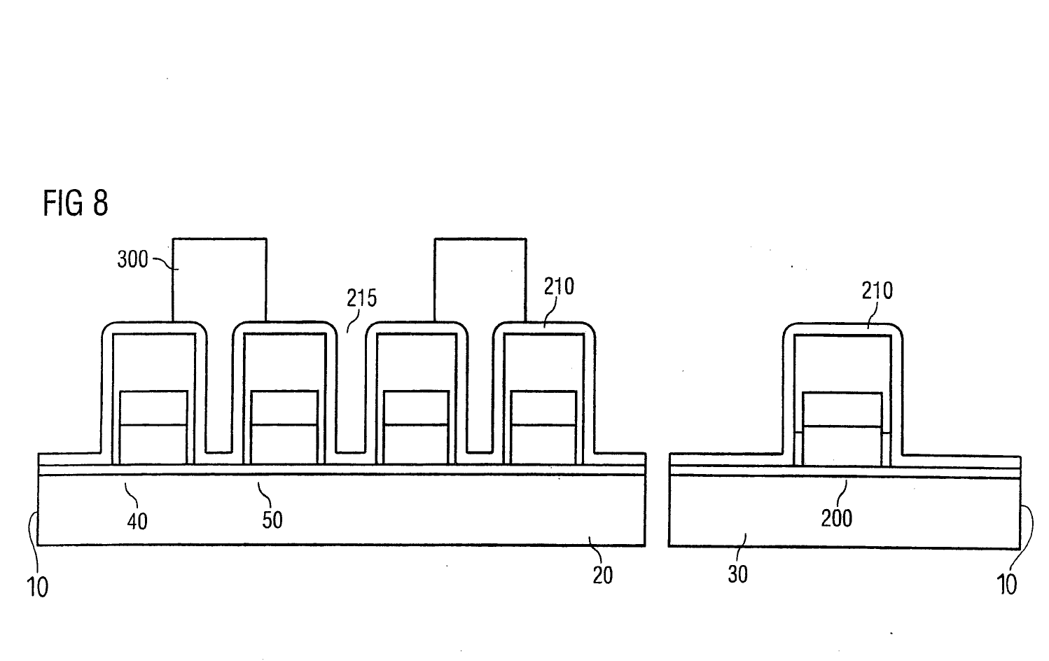

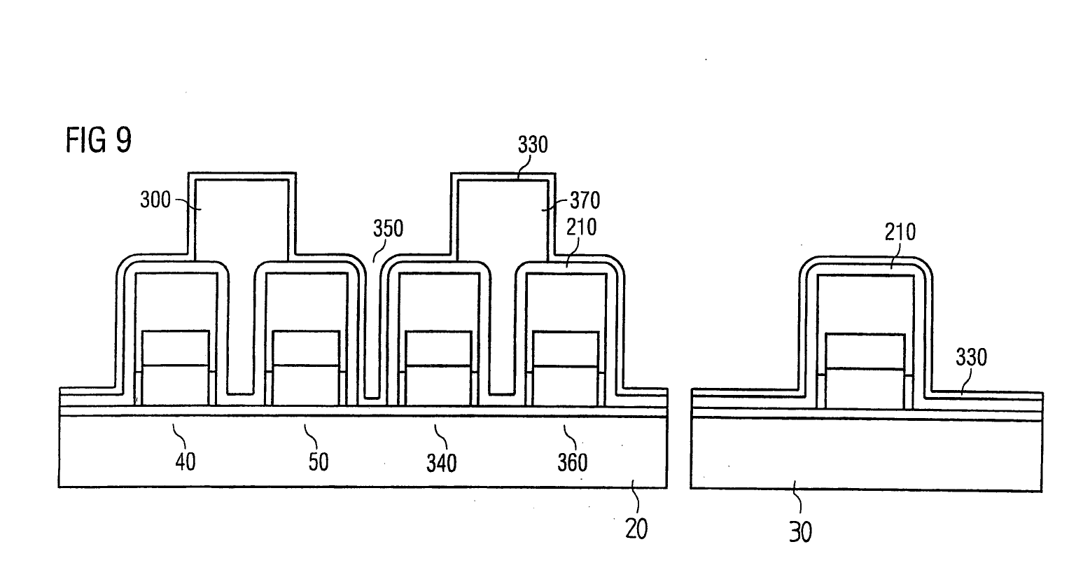

FIG. 8 shows a semiconductor substrate 10 after the mask section 270 has been completely removed. A second conformal oxide layer 330 is subsequently applied, which bears on top of the sacrificial structure 300. The second oxide layer 330—like the first oxide layer 210 as well—is preferably a TEOS oxide. This is shown in FIG. 9.

As can additionally be discerned in FIG. 9, the layer thickness of the second conformal oxide layer 300 is chosen such that a gap region 350 remains between the transistor 50 and a third n-channel field effect transistor 340 of the transistor cell region 20 that is directly adjacent on the side to the right of the transistor 50.

In the sectional plane of the semiconductor substrate 210 as shown in FIG. 9 (and FIG. 8), a fourth n-channel field effect transistor 360 is furthermore evident. A further sacrificial structure 370 is situated between said fourth transistor 360 and the third transistor 340. It is evident that the sacrificial structures are arranged in such a way that at least one gap region 350 in each case remains free between the adjacent sacrificial structures 300 and 370.

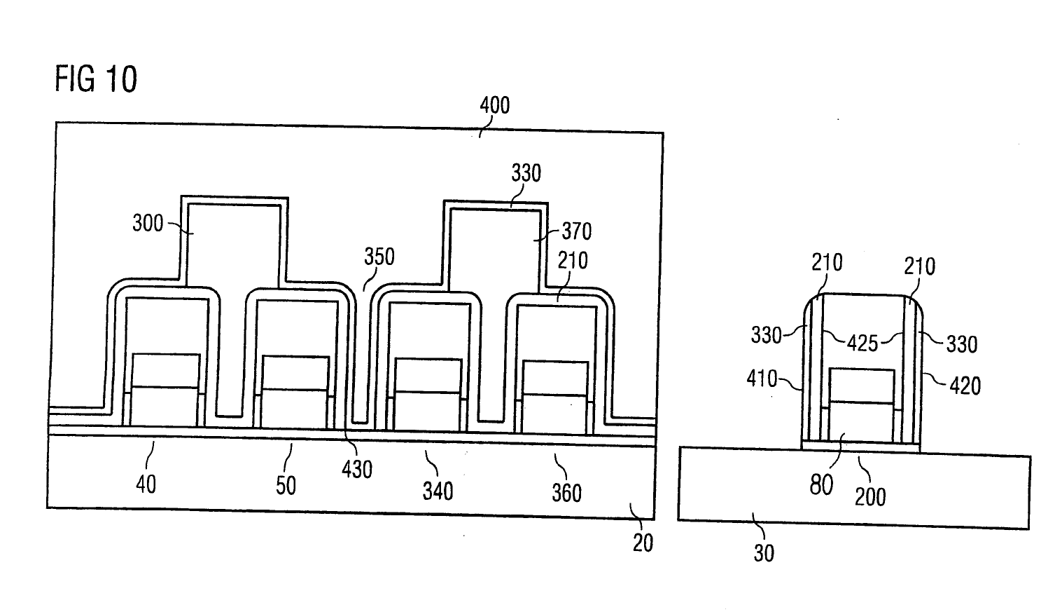

In a subsequent process step, the semiconductor structure in the transistor cell region 20 is covered with a protective layer 400, for example, a photoresist protective layer. The connection region 30 remains uncovered, so that, in an etching step, which is preferably completely or at least largely anisotropic, with the two oxide layers 210 and 330, spacers 410 and 420 are formed on the side edges 425 of the gate contacts 80 of the transistor 200. The width of the spacers 410 and 420 may—if desired—subsequently be reduced by means of a laterally etching etchant and be brought to a desired dimension. The photoresist protective layer 400 is used, during the etching of the spacers, to preserve the bottom region 430 of the gap regions 350 against “etching free” or complete removal of the oxide protective layer formed by the two oxide layers 210 and 330 and to protect the substrate. FIG. 10 shows the structure after the etching of the spacers 410 and 420.

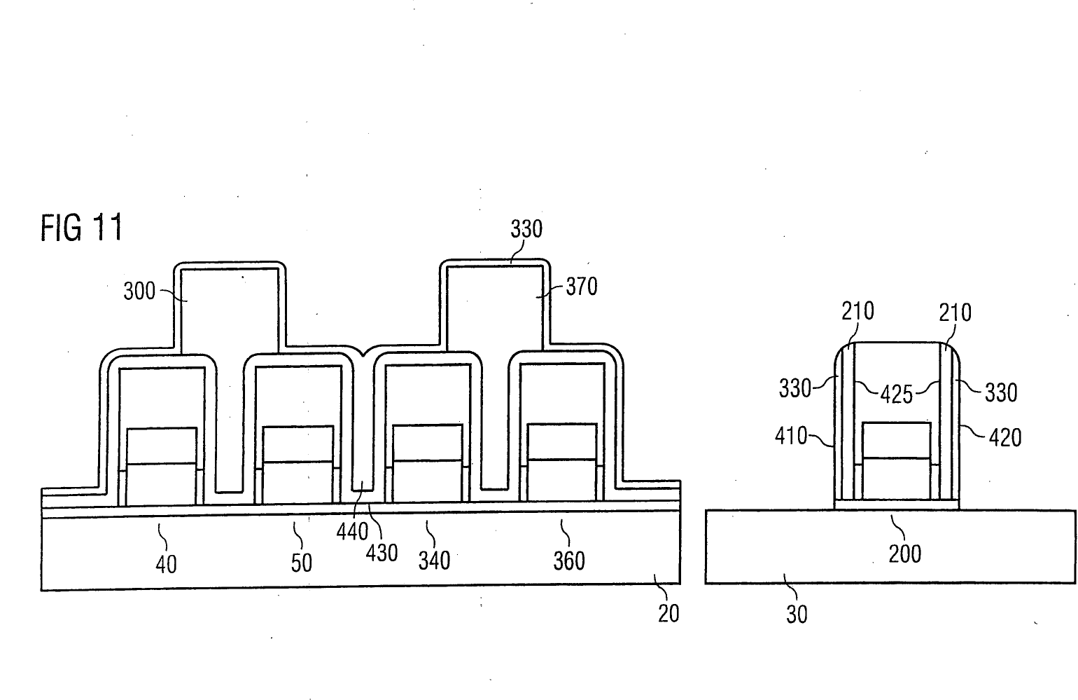

FIG. 11 illustrates a second exemplary embodiment of the invention. The starting point in this second exemplary embodiment is the structure in accordance with FIG. 8. If the thickness of the second oxide layer 330 is chosen to be large enough that it is no longer possible for the layer to be deposited conformally in the narrow gap region 350 (see FIG. 9) then the gap region 350 is closed off with the formation of an oxide plug 440. The resulting structure is shown in the left-hand part of FIG. 11 (see in contrast thereto, the structure in accordance with FIG. 9 where the gap region 350 is retained). Since, in this case, there is no risk of the bottom region 430 being etched free of the oxide 210 and 330 during the etching of the spacers 410 and 420, it is possible, in contrast to the first exemplary embodiment in accordance with FIG. 9, to dispense with the photoresist protective layer 400 (cf. FIG. 10) during the etching of the spacers.

Irrespective of whether the spacers are formed with a photoresist protective layer 400 according to the variant in accordance with FIG. 10 or without a photoresist protective layer 400 in accordance with the variant in FIG. 11, it is possible, after completion of the spacers (330, 410) to remove the sacrificial structures (300, 370) and to fabricate transistor contacts in each case in the resulting cavities. By way of example, the transistor contacts are fabricated on a source or drain contact of the respective transistors (40, 50, 340, 360).

The spacers (400, 410) may be used as a mask for an implantation step during which highly doped contact regions are formed within the source and drain region of the transistors (200) of the connection region (30).

Capacitors can also be fabricated in the region of the transistor cell region (30), said capacitors, together with the transistors (40, 50, 340, 360) of the transistor cell region, forming memory cells, in particular DRAM memory cells.

What is claimed is:

1. A method for fabricating a semiconductor structure having a transistor cell region in which transistors are arranged closely adjacent alongside one another, and having a connection region, in which transistors are at a greater distance from one another than in the transistor cell region, the method comprising:
coating the transistors both of the transistor cell region and of the connection region with a first oxide layer, the layer thickness of the first oxide layer being dimensioned in such a way that a gap region in each case remains present between adjacent transistors in the transistor cell region;
subsequently applying sacrificial structures, each sacrificial structure being applied between at least two adjacent transistors of the transistor cell region in the gap region, at least one gap region in each case remaining free between two adjacent sacrificial structures;
applying a second oxide layer (330) to the sacrificial structures and the first oxide layer; and
subjecting the first and second oxide layers to an etching step in which at least one spacer having a predetermined spacer width is formed on side edges of at least one transistor of the connection region, the spacer being formed by the first and second oxide layers and the spacer width being determined by the layer thickness of the first and second oxide layers and also by the etching step.

2. The method as claimed in claim 1, wherein the second oxide layer is deposited with a layer thickness such that the gap regions in the transistor cell region without a sacrificial structure are completely filled with oxide material.

3. The method as claimed in claim 2, wherein the width of the at least one spacer of the transistors of the connection region is set by using a single- or multi-step etching method for the etching step for etching the first and second oxide layers said etching method having not only a vertical but also a lateral etching behavior.

4. The method as claimed in claim 1, wherein the sacrificial structures are removed after completion of the at least one spacer and wherein a transistor contact is in each case fabricated in resulting cavities.

5. The method as claimed in claim 4, wherein the transistor contacts are fabricated on a source or drain contact of the respective transistor.

6. The method as claimed in claim 1, wherein the at least one spacer is used as a mask for an implantation step in which highly doped contact regions are formed within the source and drain region of the transistors of the connection region

7. The method as claimed in claim 1, wherein capacitors are fabricated in the region of the transistor cell region, said capacitors, together with the transistors of the transistor cell region, forming memory cells.

8. The method as claimed in claim 7, wherein the memory cells comprise DRAM cells.

9. The method as claimed in claim 1, wherein the transistors are fabricated as field effect transistors.

10. The method as claimed in claim 1, wherein the first oxide layer and/or the second oxide layer comprises a TEOS layer.

11. The method as claimed in claim 1, wherein the at least one spacer is formed on side edges of a gate contact of the transistors of the connection region.

12. The method as claimed in claim 10, wherein a multilayer contact is fabricated as the gate contact (80).

13. The method as claimed in claim 11, wherein the multilayer contact is formed by a polysilicon layer and an overlying metal layer.

14. A method for fabricating a semiconductor structure, the method comprising:
forming a plurality of transistors in a transistor cell region and in a connection region;
forming a first dielectric layer over the transistors of both the transistor cell region and the connection region, wherein a gap region remains between adjacent transistors in the transistor cell region;
forming sacrificial structures, each sacrificial structure being formed in the gap region between at least two adjacent transistors of the transistor cell region, at least one gap region remaining free between two adjacent sacrificial structures;
forming a second dielectric layer over the sacrificial structures and the first dielectric layer; and
etching the first and second dielectric layers to form at least one spacer at side edges of at least one transistor of the connection region.

15. The method of claim 14, wherein the first dielectric layer comprises an oxide layer and wherein the second dielectric layer comprises an oxide layer.

16. The method of claim 14, wherein the transistors are formed such that transistors in the transistor cell region are arranged adjacent alongside one another and adjacent transistors are spaced from each other by a first distance, and transistors in the connection region are spaced from each other by a second distance that is greater than the first distance.

17. The method of claim 16, further comprising:
removing the sacrificial structures after forming the at least one spacer; and
forming a transistor contact in region where a sacrificial structure has been removed.

18. The method of claim 14, wherein etching the first and second dielectric layers to form at least one spacer comprises forming the spacer from the first and second dielectric layers.

19. The method of claim 14, further comprising:
removing the sacrificial structures after forming the at least one spacer; and
forming a transistor contact in region where a sacrificial structure has been removed.
